(19) United States
(12) Patent Application Publication
(10) Pub. No.: US 2026/0206299 A1
(43) Pub. Date: Jul. 16, 2026

(54) SEMICONDUCTOR DEVICE WITH ISOLATION STRUCTURES

(71) Applicant: Taiwan Semiconductor Manufacturing Co., Ltd., Hsinchu (TW)

(72) Inventors: Chun Yi CHOU, Hsinchu (TW); Kuo-Cheng CHIANG, Hsinchu (TW); Chih-Hao WANG, Hsinchu (TW); Ka-Hing FUNG, Hsinchu (TW); Jian-Hao CHEN, Hsinchu (TW)

(73) Assignee: Taiwan Semiconductor Manufacturing Co., Ltd., Hsinchu (TW)

(21) Appl. No.: 19/216,282

(22) Filed: May 22, 2025

Related U.S. Application Data
(60) Provisional application No. 63/745,630, filed on Jan. 15, 2025.

(51) Int. Cl. H10D 84/83; H01L 21/762; H10D 30/00; H10D 30/01; H10D 30/43; H10D 62/10; H10D 62/13; H10D 84/01

(52) U.S. Cl. CPC H10D 84/832; H10D 30/014; H10D 30/0191; H10D 30/43; H10D 30/502; H10D 62/121; H10D 62/151; H10D 84/0128; H10D 84/013; H10D 84/0151; H10W 10/0143; H10W 10/17

(57) ABSTRACT

An integrated circuit includes a substrate having first, second, and third active regions extending in a first direction. The first and second active regions are closer together than are the second and third active regions. A first isolation structure is between and extends alongside the first active region and the second active region. A second isolation structure is between and extends alongside the second active region and the third active region. The first and second isolation structures have different compositions.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-14 are cross-sectional and top views of an integrated circuit at various stages of processing, in accordance with some embodiments.

FIG. 15 is a flow diagram of a method of manufacturing an integrated circuit, in accordance with some embodiments.

FIG. 16 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the disclosure provide isolation structures, such as shallow trench isolation regions, that assist in preventing defects during formation of transistors. Semiconductor fins are formed in the in an integrated circuit. Some adjacent fins are separated by relatively small distances, while other adjacent fins are separated by relatively large distances. Isolation structures are formed between adjacent fins. Formation of the isolation structures includes deposition of three dielectric layers. The first layer is a thin, low-k dielectric layer lining the fins and the trenches between the fins. The second layer is formed on the first layer and is of a different material than the first layer. The third layer is the same material as the first layer. After recessing of the isolation structures, the second layer entirely fills the trenches between fins that are separated by small distances, due to merging. The third layer is present on the second layer in trenches between fins separated by larger distances.

The isolation structures as described above provide various benefits. In particular, the isolation structures help to prevent unwanted bridging between adjacent fins during source/drain epitaxial growth processes. Additionally, the isolation structures can be formed in conjunction with a low temperature annealing process that reduces the oxidation of semiconductor materials of the fins (e.g., oxidation of SiGe layers). This results in transistors having superior electrical characteristics and better overall performance. Furthermore, this can improve wafer yields and overall function of integrated circuits and electronic devices in which the integrated circuits are embedded.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

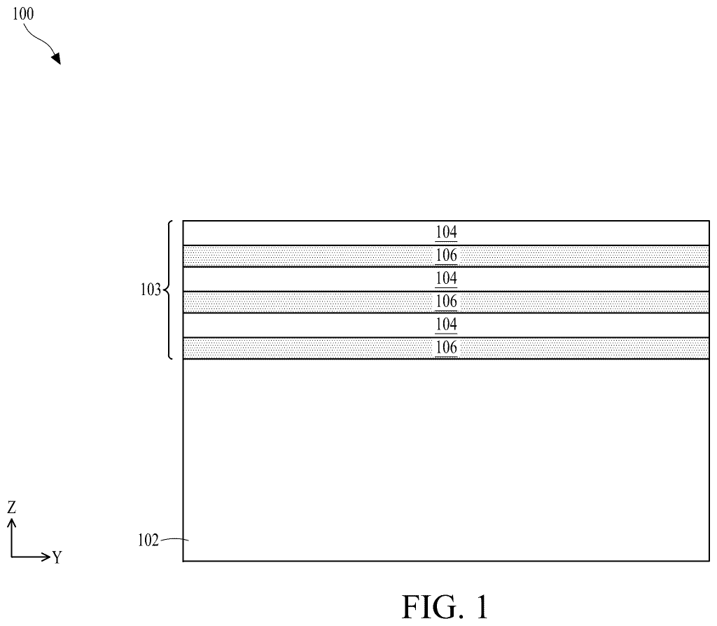

FIGS. 1-14 are cross-sectional and top views of an integrated circuit 100 fabricated in accordance with some embodiments of the present disclosure. The fabrication process results in a plurality of transistors 101, as will be described in further detail below.

FIG. 1 is a cross-sectional view of the integrated circuit 100 at an intermediate stage of processing, in accordance with some embodiments. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. In the example of FIG. 1, the stack 103 includes three semiconductor layers 104 and three sacrificial semiconductor layers 106. However, in practice, different numbers of semiconductor layers 104 and sacrificial semiconductor layers 106 can be utilized without departing from the scope of the present disclosure.

As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures.

In some embodiments, the semiconductor layers 104 are formed of a first semiconductor material, such as silicon, silicon carbide, or the like. The sacrificial semiconductor layers 106 are formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like. Other materials may be utilized without departing from the scope of the present disclosure.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In one example, the semiconductor layers 104 are silicon and the sacrificial semiconductor layers 106 are silicon germanium. In some embodiments, the sacrificial semiconductor layers 106 have a concentration of germanium between 10% and 50%, though other concentrations can be utilized without departing from the scope of the present disclosure. This enables the sacrificial semiconductor layers 106 to be selectively etchable with respect to the semiconductor layers 104. Other materials and concentrations can be utilized without departing from the scope of the present disclosure.

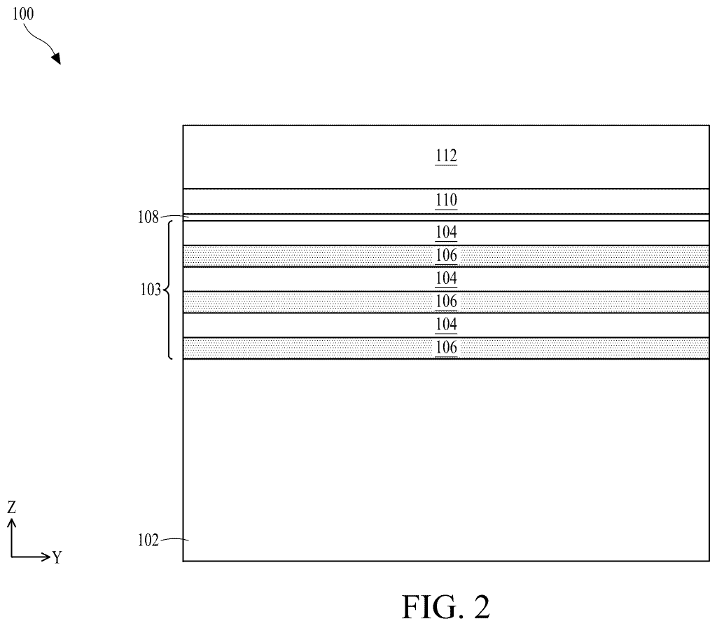

In FIG. 2, a dielectric layer 108 has been formed on the semiconductor stack 103, in accordance with some embodiments. The dielectric layer 108 includes one or more of SiO, SiN, SiON, SiCN, SiOC, SiOCN, or other suitable dielectric materials. In some embodiments, the dielectric layer 108 has a thickness between 0.5 nm and 2 nm, though other thicknesses can be utilized without departing from the scope of the present disclosure. The dielectric layer 108 can be deposited by CVD, ALD, PVD, or other suitable dielectric processes.

In FIG. 2, a dielectric layer 110 has been formed on the dielectric layer 108, in accordance with some embodiments. The dielectric layer 110 includes one or more of SiO, SiN, SiON, SiCN, SiOC, SiOCN, or other suitable dielectric materials. In some embodiments, the dielectric layer 110 has a thickness between 5 nm and 20 nm, though other thicknesses can be utilized without departing from the scope of the present disclosure. The dielectric layer 110 can be deposited by CVD, ALD, PVD, or other suitable dielectric processes.

In FIG. 2, a dielectric layer 112 has been formed on the dielectric layer 110, in accordance with some embodiments. The dielectric layer 112 includes one or more of SiO, SiN, SiON, SiCN, SiOC, SiOCN, or other suitable dielectric materials. In some embodiments, the dielectric layer 112 has a thickness between 5 nm and 20 nm, though other thicknesses can be utilized without departing from the scope of the present disclosure. The dielectric layer 112 can be deposited by CVD, ALD, PVD, or other suitable dielectric processes.

In some embodiments, the dielectric layer 108 includes silicon oxide, the dielectric layer 110 includes silicon nitride, and the dielectric layer 112 includes silicon oxide. Other combinations of layers, and materials can be utilized without departing from the scope of the present disclosure.

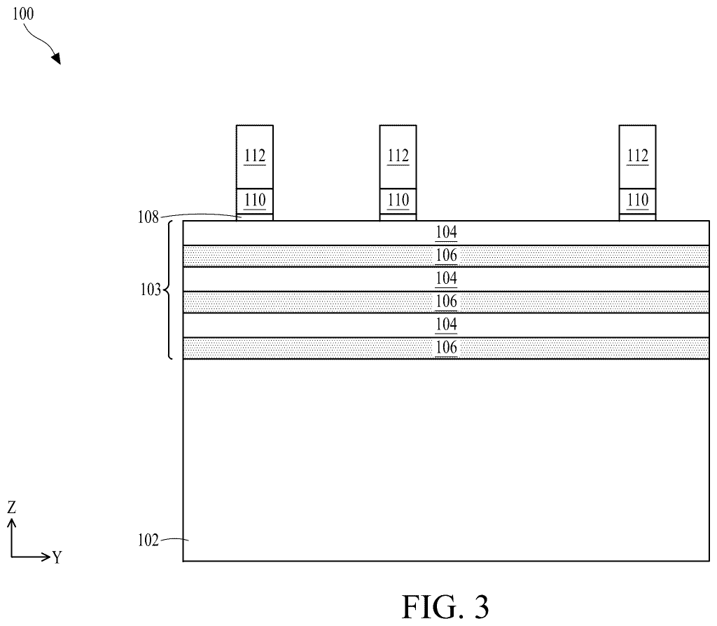

In FIG. 3, the dielectric layers 108, 110, and 112 have been patterned in accordance with a photolithography process, in accordance with some embodiments. The photolithography process forms a pattern hard mask from the dielectric layers 108, 110, and 112. As will be set forth in more detail below, the pattern of the hard mask corresponds to a pattern of trenches to be formed in the semiconductor stack 103 and the substrate 102.

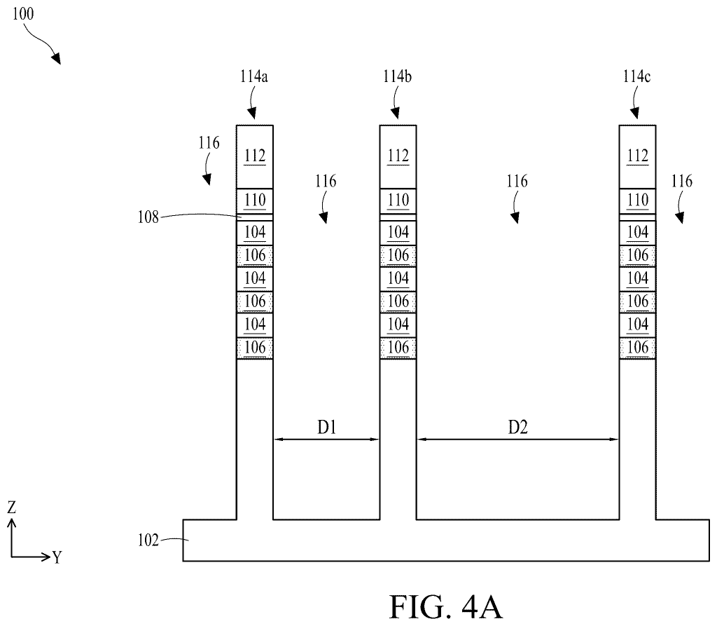

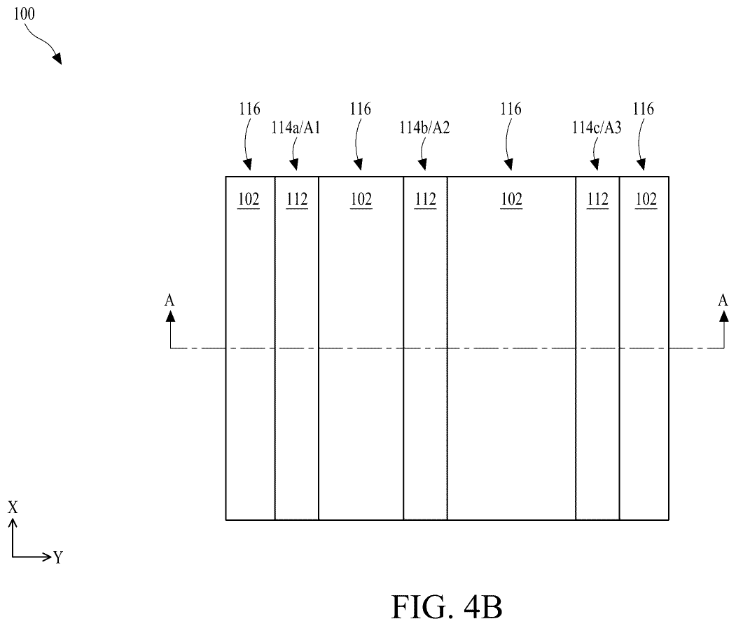

In FIG. 4A, a plurality of semiconductor fins 114a-c have been formed from the stack 103. Throughout the specification, some reference numbers may have a suffix a, b, c, or d (e.g., semiconductor fins 114a, 114b, and 114c). The suffix letters may be used or omitted based on context. For example, if reference is specific to the semiconductor fin 114a, then the suffix “a” is used. However, if the reference is generic to all of the semiconductor fins 114, then the suffixes are omitted. This pattern of using and omitting suffix letters in reference numbers is carried to other reference numbers herein.

The semiconductor fins 114 are formed by forming trenches 116 in the stack 103 and in the substrate 102. The trenches 116 can be formed with an anisotropic etching process that etches in the downward direction in the presence of the patterned hard mask. The etching process defines semiconductor fins 114 by forming trenches 116 through the sacrificial semiconductor layers 106, the semiconductor layers 104, and the substrate 102. The etching process can utilize a single etching step or multiple etching steps.

The fins 114a and 114b are separated by a dimension D1 in the Y direction. In other words, the trench 116 that separates the fins 114a and 114b has a width dimension D1 in the Y direction. The fins 114b and 114c are separated by a dimension D2 in the Y direction. In other words, the trench 116 that separates the fins 114b and 114c has a width dimension D2 in the Y direction. FIG. 4A, illustrates three fins 114. However, in practice, the integrated circuit 100 can have regions of large numbers of densely packed fins 114 that are each separated by the smaller the dimension D1. The integrated circuit 100 can also have isolation regions in which adjacent fins 114 are separated by the larger separation distance D2. The larger separation distance D2 is utilized when circuit design or other considerations call for increased electrical isolation. For example, a plurality of transistors will be formed in each fin 114. When larger electrical isolation is called for between transistors of adjacent fins, the larger separation distance D2 is utilized. In some embodiments, D1 is between 15 nm and 50 nm. In some embodiments, D2 is between 30 nm and 100 nm. Other dimensions can be utilized without departing from the scope of the present disclosure.

FIG. 4B is a top view of the integrated circuit 100 at the stage of processing shown in FIG. 4A, in accordance with some embodiments. The top view of FIG. 4B illustrates the semiconductor fins 114a-c extending in the X direction. The top view of FIG. 4B illustrates the trenches 116 extending in the X direction and separating the fins 114 from each other in the Y direction. Though not shown in FIG. 4B, the integrated circuit 100 can include a large number of fins 114. At the stage of processing shown in FIG. 4B, the dielectric layer 112 is present on top of the fins 114. The substrate 102 is exposed in the bottom of the trenches 116. The view of FIG. 4A is taken along the cut lines A of FIG. 4B.

The semiconductor fins 114 may also be termed “active regions”. A plurality of transistors will be formed in conjunction with each semiconductor fin. In some embodiments, each semiconductor fin 114 is formed at an active region. Accordingly, the locations of the semiconductor fins 114a-c are also labeled A1-A3.

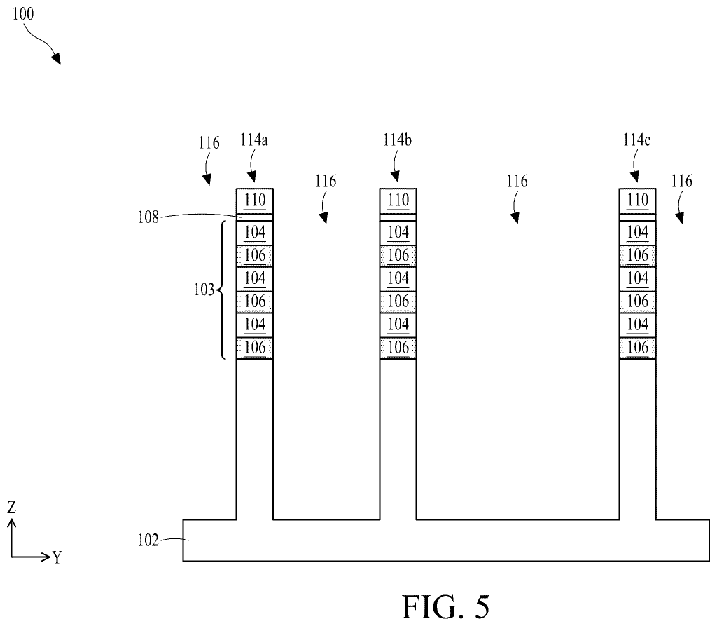

FIG. 5 is a cross-sectional view of the integrated circuit 100, in accordance with some embodiments. In FIG. 5, the dielectric layer 112 has been removed from the tops of the fins 114. The dielectric layer 112 can be removed with an etching process that selectively etches the material of the dielectric layer 112 with respect to the material of the dielectric layer 110 and the substrate 102. The etching process can include an anisotropic etching process that etches in the downward direction.

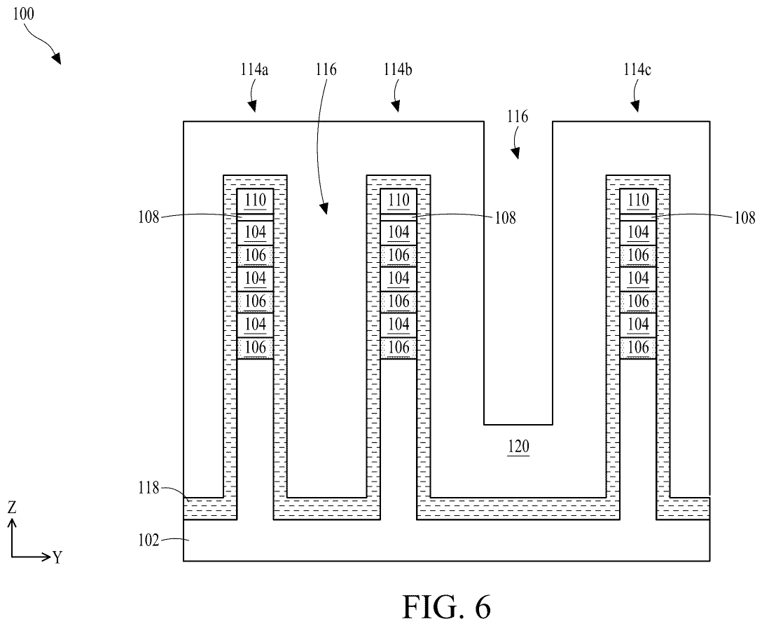

FIG. 6 is a cross-sectional view of the integrated circuit 100, in accordance with some embodiments. In FIG. 6, a dielectric layer 118 has been deposited. The dielectric layer 118 is conformally deposited on the sidewalls of the fins 114 and on the substrate 102, exposed at the bottom of the trenches 116. The dielectric layer 118 has a thickness between 1 nm and 10 nm, though other thicknesses can be utilized without departing from the scope of the present disclosure. The dielectric layer 118 is deposited by CVD, ALD, PVD, or other suitable deposition processes. The dielectric layer 118 includes SiO or other suitable dielectric materials. In a particular example illustrated herein, the dielectric layer 118 includes silicon oxide. As will be set forth in more detail below, the dielectric layer 118 will be part of an isolation structure, such as a shallow trench isolation structure.

In FIG. 6, a dielectric layer 120 has been deposited. The dielectric layer 120 is conformally deposited on the dielectric layer 118. The dielectric layer 120 has a thickness between 5 nm and 50 nm, though other thicknesses can be utilized without departing from the scope of the present disclosure. The dielectric layer 120 is deposited by CVD, ALD, PVD, or other suitable deposition processes. The dielectric layer 120 includes SiN, SiON, SiCN, SiOC, SiOCN, or other suitable dielectric materials. In a particular example illustrated herein, the dielectric layer 120 includes silicon nitride. As will be set forth in more detail below, the dielectric layer 120 will be part of an isolation structure, such as a shallow trench isolation structure.

As can be seen in FIG. 6, the dielectric layer 120 entirely fills the remaining portion of the trench 116 between the fins 114a and 114b. In other words, the deposition thickness of the dielectric layer 120 results in the dielectric layer 120 growing from opposite sides of the trench 116 until the dielectric layer 120 merges with itself and fills the trench 116 between the fins 114a and 114b. However, at the wider trench 116 between the fins 114b and 114c, the dielectric layer 120 is not thick enough to merge. The result is that there is still an unfilled gap in the trench 116 between the fins 114b and 114c.

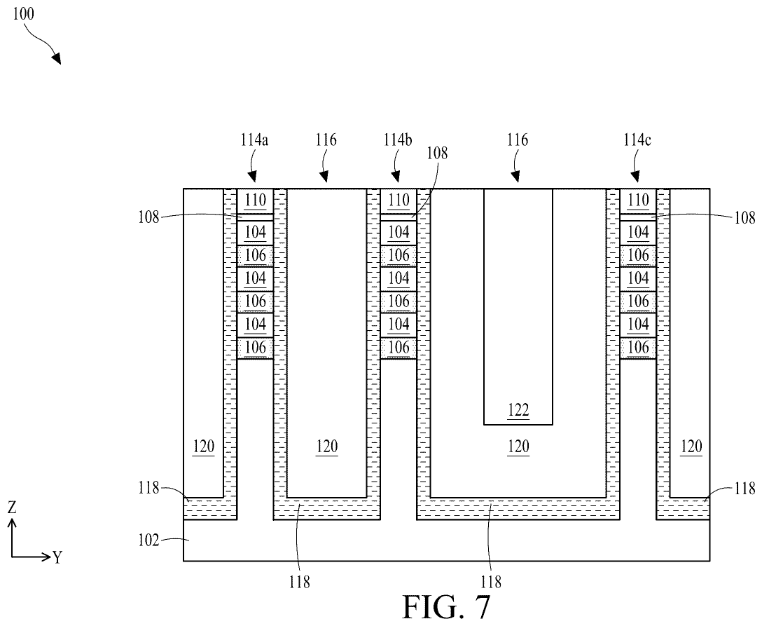

FIG. 7 is a cross-sectional view of the integrated circuit 100, in accordance with some embodiments. In FIG. 7, a dielectric layer 122 has been deposited. The dielectric layer 122 is deposited on the dielectric layer 120. The dielectric layer 122 includes SiO or other suitable dielectric materials. In a particular example illustrated herein, the dielectric layer 122 includes silicon oxide. As will be set forth in more detail below, the dielectric layer 122 will be part of an isolation structure, such as a shallow trench isolation structure.

In some embodiments, the dielectric layer 122 is formed by a flowable CVD (FCVD) process. The FCVD processes utilized filling gaps in the trenches 116, where high aspect ratios are present. In the FCVD process, silane and other precursors (such as hydrogen peroxide) flowed into the environment of the integrated circuit (e.g., in a deposition chamber). The precursors are activated using an oxygen-based plasma or in another manner, resulting in a liquid or liquid-like material that flows into the trenches 116. A low-temperature thermal annealing process is then performed to cure the dielectric layer 122, resulting in a layer of silicon oxide or other selected material.

The low temperature thermal annealing process is selected to help ensure that the dielectric layer 122 fully forms without damaging the sacrificial semiconductor layers 106. In some examples, the sacrificial semiconductor layers 106 includes silicon germanium. The silicon germanium is particularly susceptible to oxidation during a high temperature thermal annealing process. Accordingly, embodiments of the present disclosure utilize a low temperature thermal annealing process to help prevent oxidation of the sacrificial semiconductor layers 106. In some embodiments, the low temperature thermal annealing process is performed at a temperature between 400° C. and 700° C. If the temperature is less than 400° C., then the dielectric layer 122 may not be fully cured and the uniformity is poor. If the temperature is greater than 700° C., then the thermal budget may be too high and the unwanted oxidation of the sacrificial semiconductor layers 106 may occur.

As can be seen in FIG. 7, the dielectric layer 122 is present in the trench 116 between the fins 114b and 114c. This is because the dielectric layer 120 does not fully fill the wider isolation trenches. The dielectric layer 122 is not present in the trench 116 between the fins 114a and 114b because the dielectric layer 120 has merged and fully filled the narrow trenches in denser fin regions.

In FIG. 7, a CMP process has been performed. The CMP process removes the material of the dielectric layers 118, 120, and 122 above a level of the top of the dielectric layer 110 on the fins 114. The result of the CMP process is that the top surfaces of the dielectric layers 110, 118, 120, and 122 are coplanar.

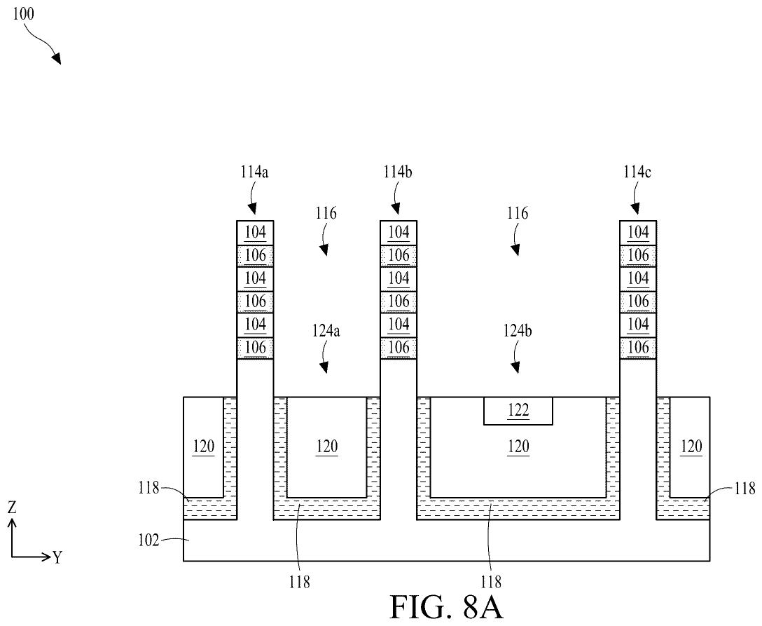

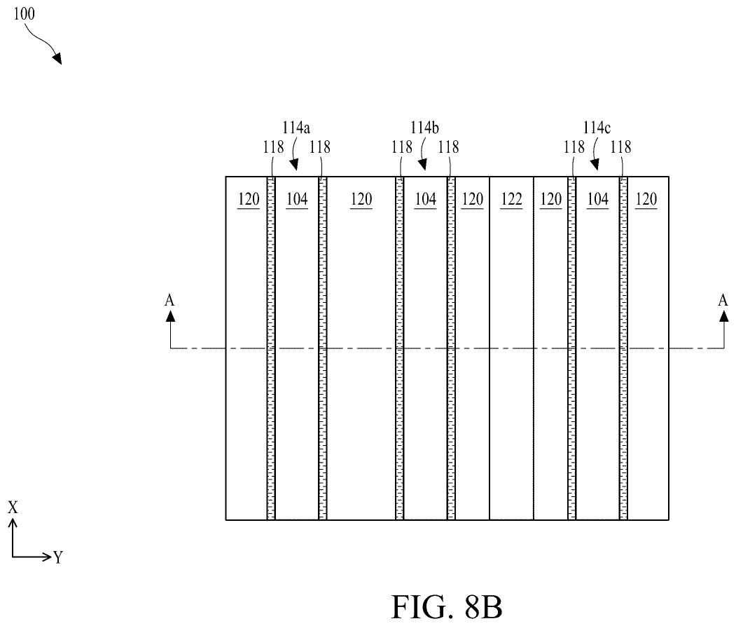

FIG. 8A is a cross-sectional view of the integrated circuit 100, in accordance with some embodiments. FIG. 8B is a top view of the integrated circuit 100 at the stage of processing shown in FIG. 8A. The cross-sectional view of FIG. 8A is taken along cut lines A from FIG. 8B.

In FIG. 8A, a recessing process has been performed, in accordance with some embodiments. The recessing process includes one or more etching processes that recess the top surfaces of the dielectric layers 118, 120, and 122 to a level lower than the bottom surfaces of the lowest sacrificial semiconductor layers 106.

In FIG. 8A, isolation structures 124 have been formed. The isolation structures 124 correspond to shallow trench isolation regions, in accordance with some embodiments. The isolation structure 124a is formed between the fins 114a and 114b in the dense fin region. The isolation structure 124b is formed between the fins 114b and 114c in the isolation region. The isolation structure 124a does not include the dielectric layer 122 due to the merging of the dielectric layer 120 in the narrower trench 116, as described previously. In the isolation structure 124a, the dielectric layer 118 has a U-shaped profile in the Y-Z plane. In the isolation structure 124a, the dielectric layer 120 does not have a U-shaped profile in the Y-Z plane, but has a continuous top surface with no gap.

The isolation structure 124b includes the dielectric layer 122 on the dielectric layer 120. In some embodiments, the dielectric layer 122 has a width in the Y direction between 20 nm and 300 nm. In some embodiments, the dielectric layer 122 has a height in the Z direction between 1 nm and 50 nm. Other dimensions can be utilized without departing from the scope of the present disclosure. In the isolation structure 124b, the dielectric layer 118 has a U-shaped profile in the Y-Z plane. In the isolation structure 124b, the dielectric layer 120 has a U-shaped profile in the Y-Z plane. In the isolation structure 124b, the dielectric layer 122 does not have a U-shaped profile in the Y-Z plane, but has a continuous top surface with no gap.

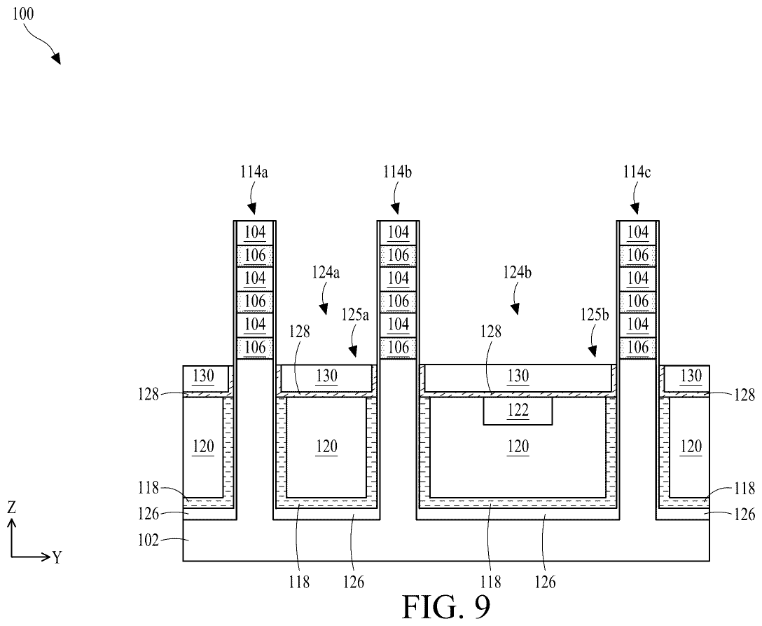

FIG. 9 is a cross-sectional view of the integrated circuit 100, in accordance with some embodiments. FIG. 9 illustrates a semiconductor liner layer 126 that was not shown in previous Figures. In some embodiments, the liner layer 126 is formed via epitaxial growth at the stage of processing shown in FIG. 4A. In other words, after formation of the trenches 116, an epitaxial growth process is performed to grow the thin semiconductor liner layer 126. In some embodiments, the semiconductor liner layer includes silicon and has a thickness less than 1 nm. In some embodiments, the semiconductor liner layer 126 present. In some embodiments, the semiconductor liner layer 126 is not present. In some embodiments, the liner layer 126 is formed by CVD, ALD, PVD, or other deposition processes. In some embodiments, the liner layer 126 includes silicon nitride, though other materials can be utilized without departing from the scope of the present disclosure.

In FIG. 9, a dielectric layer 128 has been deposited. In some embodiments, the dielectric layer 128 includes silicon oxide, though other dielectric materials can be utilized without departing from the scope of the present disclosure. The dielectric layer 128 is conformally deposited on all exposed surfaces. Most notably, the dielectric layer 128 is deposited on exposed sidewalls of the substrate and on top surfaces of the dielectric layers 118, 120, and 122. The dielectric layer 128 can be deposited by CVD, ALD, or other suitable deposition processes. In some embodiments, the dielectric layer 128 has a thickness between 0.5 nm and 1 nm, though other thicknesses can be utilized without departing from the scope of the present disclosure.

In FIG. 9, a dielectric layer 130 has been deposited. In some embodiments, the dielectric layer 130 includes silicon nitride, though other dielectric materials can be utilized without departing from the scope of the present disclosure. The dielectric layer 130 is deposited on the dielectric layer 128. The dielectric layer 130 can be deposited by CVD, ALD, or other suitable deposition processes.

In FIG. 9, a recessing process has been performed. In some embodiments, the recessing process recesses the top surfaces of the dielectric layer 128 and the dielectric layer 130 to a level lower than a bottom surfaces of the lowest sacrificial semiconductor layers 106. The recessing process can include an initial CMP process followed by one or more etching steps that selectively etch the materials of the dielectric layers 128 and 130 with respect to other exposed materials. In some embodiments, the dielectric layers 128 and 130 correspond to a hard mask structure 125 of the isolation regions 124. The hard mask structures 125 protects the dielectric layers 118, 120, and 122 of the isolation structures 124. In some embodiments, the top surfaces of the dielectric layer 128 and the dielectric layer 130 are level with bottom surfaces of the lowest sacrificial semiconductor layers 106.

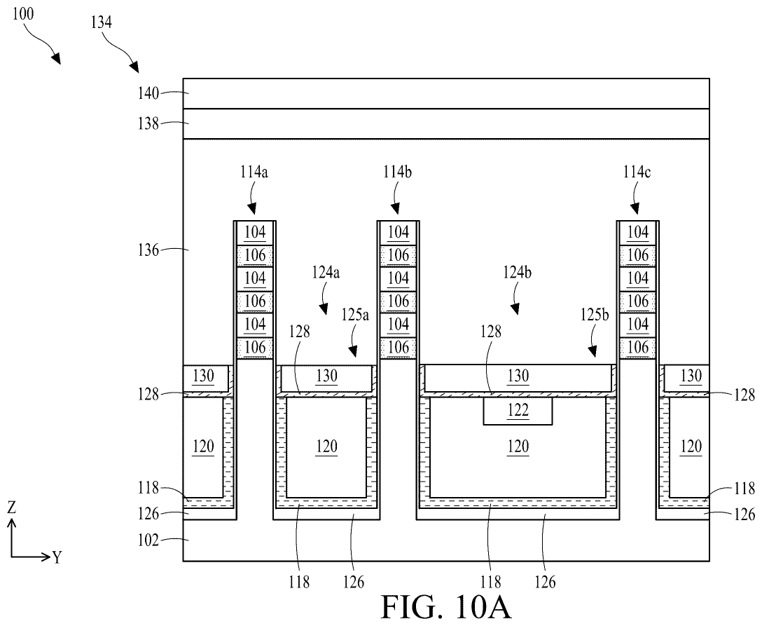

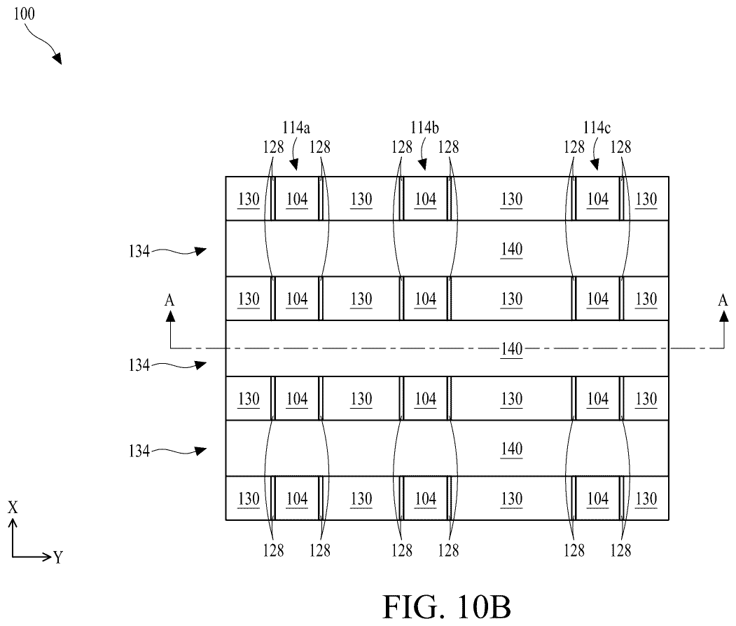

FIG. 10A is a cross-sectional view of the integrated circuit 100, in accordance with some embodiments. FIG. 10B is a top view of the integrated circuit 100 at the stage of processing shown in FIG. 10A. The cross-sectional view of FIG. 10A is taken along cut lines A from FIG. 10B.

In FIGS. 10A and 10B, sacrificial gate structures 134 have been formed over the fins 114. With reference to FIG. 10B, a plurality of sacrificial gate structures each extend parallel to each other over the fins 114 and the isolation structures 124 in the Y direction.

The sacrificial gate structures 134 include a sacrificial gate layer 136. The sacrificial gate layer 136 can include materials that have a high etch selectivity with respect to the isolation structures 124. In an exemplary embodiment, the sacrificial gate layer 136 includes polysilicon. However, the sacrificial gate layer 136 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 136 may be deposited by physical vapor deposition (PVD), CVD, sputter deposition, or other techniques for depositing the selected material.

The sacrificial gate structures 134 include a dielectric layer 138 on the sacrificial gate layer 136, in accordance with some embodiments. The dielectric layer 138 includes one or more of SiN, SiON, SiCN, SiOCN, SiOC, or other suitable dielectric materials. The dielectric layer 138 can be deposited by ALD, CVD, PVD, or other suitable deposition processes.

The sacrificial gate structures 134 include a dielectric layer 140 on the dielectric layer 138, in accordance with some embodiments. The dielectric layer 140 includes one or more of SiO, SiN, SiON, SiCN, SiOCN, SiOC, or other suitable dielectric materials. The dielectric layer 140 can be deposited by ALD, CVD, PVD, or other suitable deposition processes. In practice, the dielectric layer 140 is utilized as a hard mask for patterning the sacrificial gate structures 134. In particular, the dielectric layer 140 is patterned, in accordance with a photolithography process. In the pattern of the sacrificial gate structures 134. The dielectric layer 138 and the sacrificial gate layer 136 are then etched in the presence of the dielectric layer 140 to form the sacrificial gate structures 134.

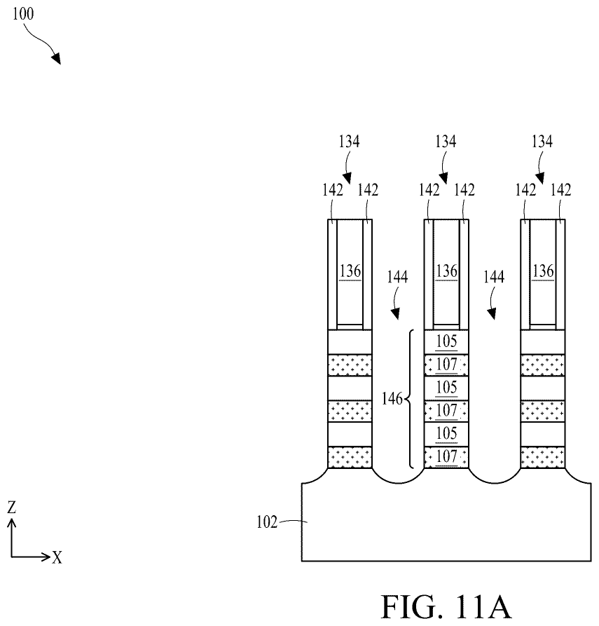

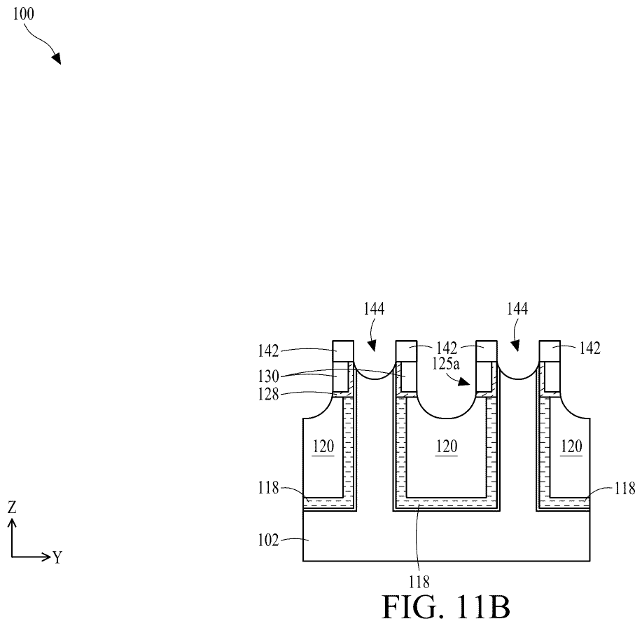

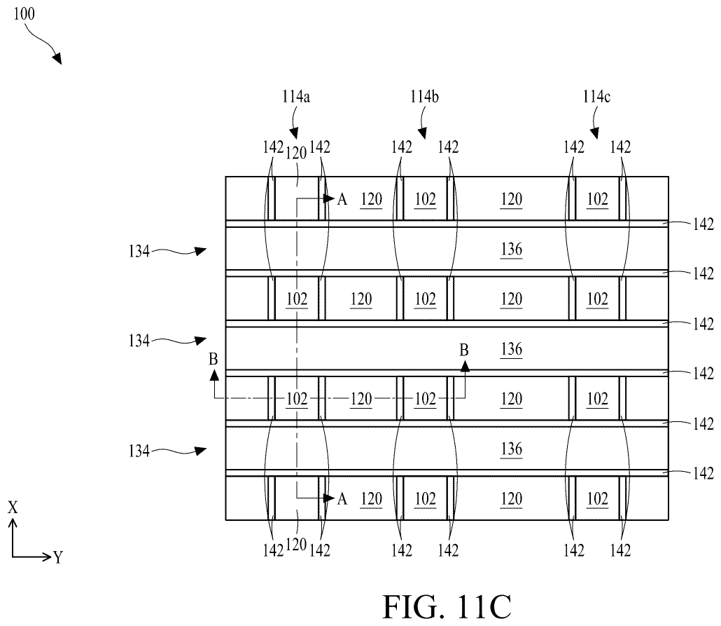

FIG. 11A is a cross-sectional view of the integrated circuit 100, in accordance with some embodiments. FIG. 11B is a cross-sectional view of the integrated circuit 100, in accordance with some embodiments. FIG. 11C is a top view of the integrated circuit 100, in accordance with some embodiments. The cross-sectional view of FIG. 11A is taken along cut lines A from FIG. 11C. The cross-sectional view of FIG. 11B is taken along cut lines B from FIG. 11C.

In FIGS. 11A-11C, a gate spacer layer 142 has been formed on the sidewalls of the sacrificial gate structures 134. The gate spacer layer 142 can include one or more of SiO, SiN, SiON, SiCN, SiOCN, SiOC, or other suitable dielectric materials. The gate spacer layer 142 is deposited by CVD, ALD, PVD, or other suitable deposition processes. The thickness of the gate spacer layer 142 is between 2 nm and 10 nm, though other dimensions can be utilized without departing from the scope of the present disclosure.

Initially, the gate spacer layer 142 is conformally deposited on all exposed surfaces, including the sidewalls of the sacrificial gate structures 134, the top surface of the fins 114 between adjacent sacrificial gate structures 134, the sidewalls of the trenches 116, and the top surface of the dielectric layers 128 and 130.

Following formation of the gate spacer layer 142, portions of the gate spacer layer on horizontal surfaces (e.g., in the X-Y plane) are removed by an anisotropic etching process that etches in the downward direction. The anisotropic etching process is timed so that vertically thinner portions of the gate spacer layer 142 are removed, while vertically thicker portions of the gate spacer layer 142 remain. This exposes upper surfaces of the fins 114 and the top surface of the sacrificial gate layer 136. The gate spacer layer 142 remains on sidewalls of the sacrificial gate structures 134 as seen in FIG. 11A. A portion of the gate spacer layer 142 also remains on the top surface of the dielectric layers 128 and 130 adjacent to sidewalls of the substrate 102 in the trenches 116, as seen in FIG. 11B.

After patterning of the gate spacer layer 142, the gate spacer layer 142 is utilized as a hard mask for forming source/drain trenches 144 in the fins 114. In particular, an anisotropic etching process is performed that etches in the downward direction and selectively etches the semiconductor material of the substrate 102 with respect to the material of the gate spacer layer 142.

Forming the source/drain trenches 144 includes etching through each of the semiconductor layers 104, each of the sacrificial semiconductor layers 106, and a portion of the substrate 102 at locations exposed by the gate spacer layer 142. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

As shown in FIG. 11A, formation of the source/drain trenches 144 results in formation of stacks 146 of channels 105. In particular, the remaining portions of the semiconductor layers 104 after formation of the source/drain trenches 144 now correspond to stacked channels 105 of a transistor. Formation of the source/drain trenches 144 results in formation of a plurality of sacrificial semiconductor nanostructures 107 from the sacrificial semiconductor layers 106.

As shown in FIG. 11B, formation of the source/drain trenches 144 also results in forming a recess in the isolation structures 124. In particular, exposed portions of the dielectric layers 130 and 128 are removed. A recess is formed in the dielectric layer 120. However, due to the formation of the isolation structures 124 and the isolation structure hard mask structure including the dielectric layers 128 and 130, only a small amount of the isolation structures 124 is removed. Most notably, sidewalls of the substrate 102 are not exposed by removal of the isolation structures 124. This helps to ensure that there is not bridging of semiconductor material between adjacent fins 114 during subsequent epitaxial growth processes described below.

The top view of FIG. 11C illustrates the locations of the gate spacer layer 124, the source/drain trenches 144, and the exposed portions of the dielectric layer 120. Though not shown in FIG. 11C, a portion of the dielectric layer 122 may also be recessed during formation of the source/drain trenches 144.

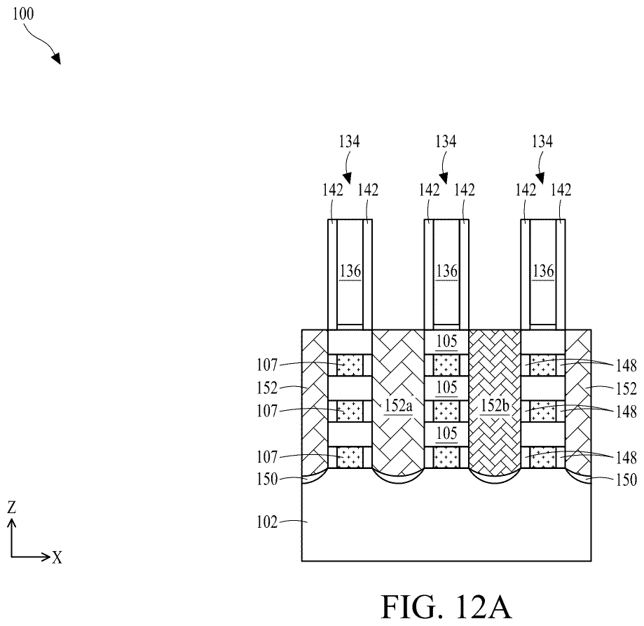

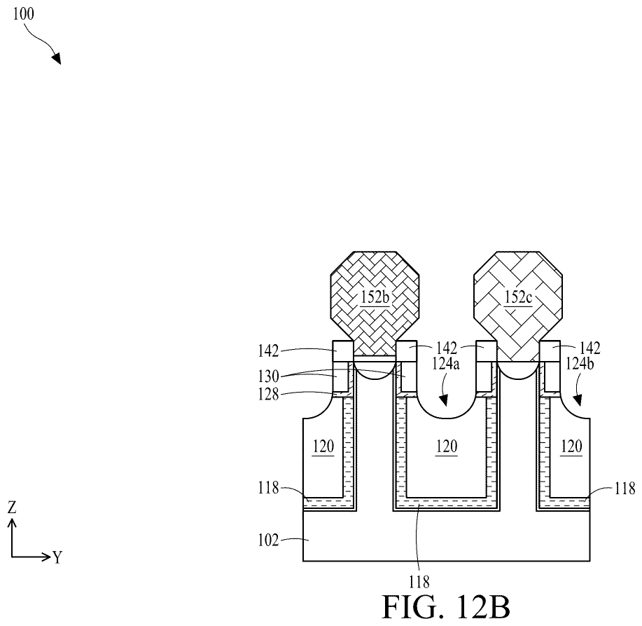

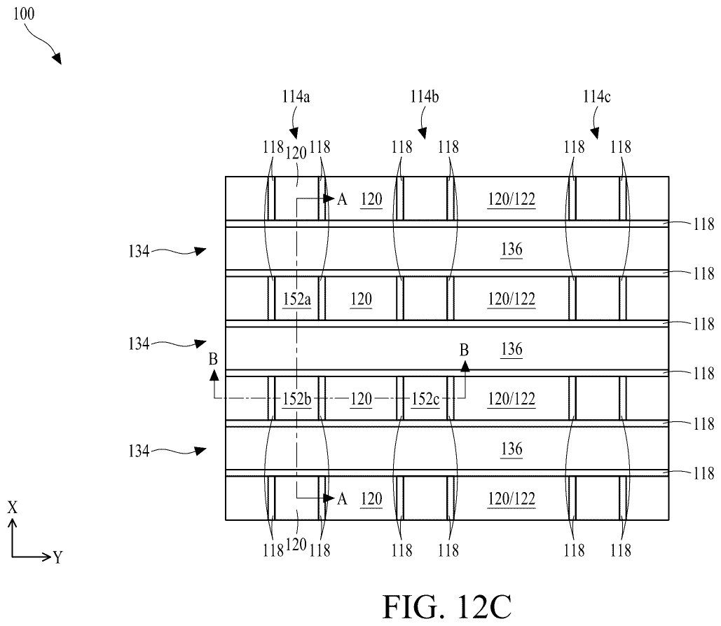

FIG. 12A is a cross-sectional view of the integrated circuit 100, in accordance with some embodiments. FIG. 12B is a cross-sectional view of the integrated circuit 100, in accordance with some embodiments. FIG. 12C is a top view of the integrated circuit 100, in accordance with some embodiments. The cross-sectional view of FIG. 12A is taken along cut lines A from FIG. 12C. The cross-sectional view of FIG. 12B is taken along cut lines B from FIG. 12C.

In FIG. 12A, a selective etching process is performed to recess exposed end portions of the sacrificial semiconductor nanostructures 107 without substantially etching the channels 105. More particularly, recesses are formed in the sacrificial semiconductor nanostructures 107 adjacent channels 105, or between the lowest channel 105 and the substrate 102. The recesses can be formed by performing an etching process that selectively etches the material of the sacrificial semiconductor nanostructures 107 with respect to the material of the channels 105 and the substrate 102. A dielectric layer is then deposited in a conformal deposition process on exposed surfaces of the channels 105, the gate spacer layer 142, the sacrificial semiconductor nanostructures 107, and the substrate 102. Most notably, the dielectric layer fills the recesses. The dielectric layer can include SiCN, SiOCN, SiON, SiN, or other suitable dielectric materials. The dielectric layer can be formed by a suitable deposition method such as CVD, ALD, PVD, or other deposition processes. Inner spacers 148 have also been formed in the recesses. The inner spacers 148 are in contact with ends of the sacrificial semiconductor nanostructures 107 and with the channels 105. As will be set forth in further detail below, the inner spacers 148 separate gate metals from source/drain regions.

In FIGS. 12A-12C, interposing layers 150 have been formed in the bottoms of the source/drain trenches 144. In some embodiments, the bottom interposing layers 150 include an intrinsic semiconductor material, such as intrinsic silicon or another suitable material. Interposing layers 150 can be a semiconductor layer, such as Si, SiGe, undoped Si layer, undoped SiGe layer. In some embodiments, interposing layers 150 can be dielectric layers, such as SiN, SiCN, SiON or other dielectric materials. In some embodiments, the interposing layers 150 can include multiple layers, including semiconductor layer and dielectric layer described above.

In FIGS. 12A-12C, source/drain regions 152 have been formed in the source/drain trenches 144, in accordance with some embodiments. The source/drain regions 152 are epitaxially grown from the channels 105. The source/drain regions 152 are grown on exposed portions of the fins 114 and contact the channels 105. For each stack 146 of channels 105, there are two source/drain regions 152. Some stacks 146 of channels 105 may share a source/drain region 152 with a stack 146 of channels 105 that is adjacent in the X direction.

In FIG. 12A, source/drain regions 152a and 152b are labeled specifically on either side of the central stack 146 of channels 105. In FIG. 12B, source/drain regions 152b and 152 c are specifically labeled. In some embodiments, the source/drain regions 152a/b are source/drain regions of an N-channel transistor. In some embodiments, the source/drain region 152c is a source/drain region of a P-channel transistor.

The source/drain regions 152 may include any acceptable semiconductor material, such as appropriate for N-type or P-type devices. For N-type regions, the source/drain regions 152 include materials exerting a tensile strain in the channel regions, such as silicon, SiC, SiCP, SiP, or the like, in some embodiments. For P-type transistors, the source/drain regions 152 include materials exerting a compressive strain in the channel regions, such as SiGe, SiGeB, Ge, GeSn, or the like, in accordance with some embodiments. The source/drain regions 152 may have surfaces raised from respective surfaces of the fins and may have facets. Neighboring source/drain regions 152 may merge in some embodiments to form a singular source/drain region 144 over two neighboring fins 114.

In some embodiments, an in-situ doping process may be performed during formation of the source/drain regions 152 to implant to the source/drain regions 152 with N-type dopants or P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 152 may be implanted with dopants followed by an annealing process. The source/drain regions 152 may have an impurity concentration of between about 10¹⁹ cm⁻³ and about 10²¹ cm⁻³.

FIG. 12B illustrates the source/drain regions 152b and 152c, in accordance with some embodiments. The source/drain regions 152b/c are laterally pounded on the lower end by the gate spacer layer 142. FIG. 12B also illustrates a bottom isolation layer 154 separating the source/drain region 152b from the substrate 102. The bottom isolation layer 154 can include SiN, SiC, SiOC, SiOCN, SiON, or other suitable dielectric materials. The bottom isolation layer 154 may also be present below the source/drain region 152a and below other N-type source/drain regions.

The top view of FIG. 12C illustrates the relative layout of the various structures, in accordance with some embodiments.

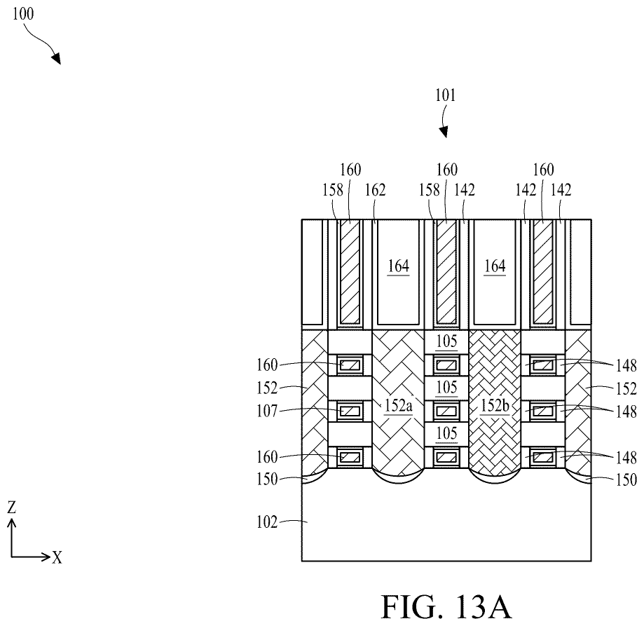

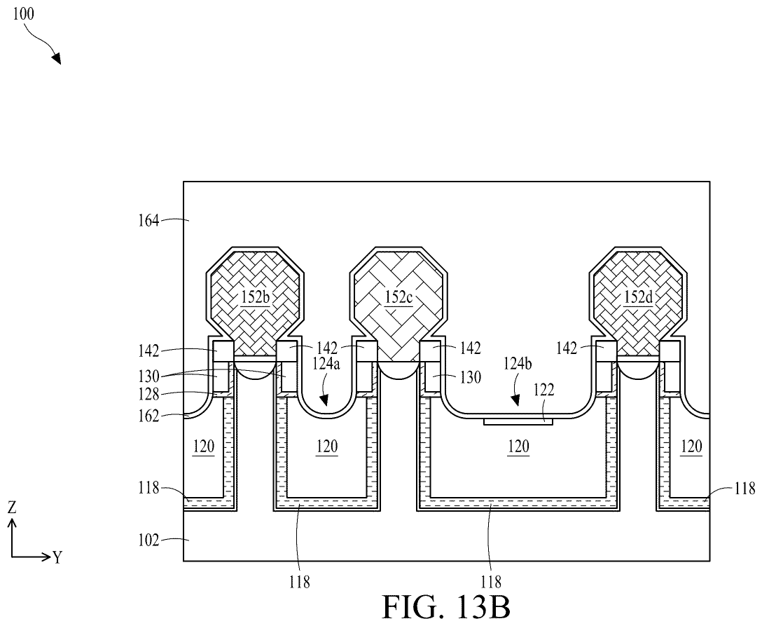

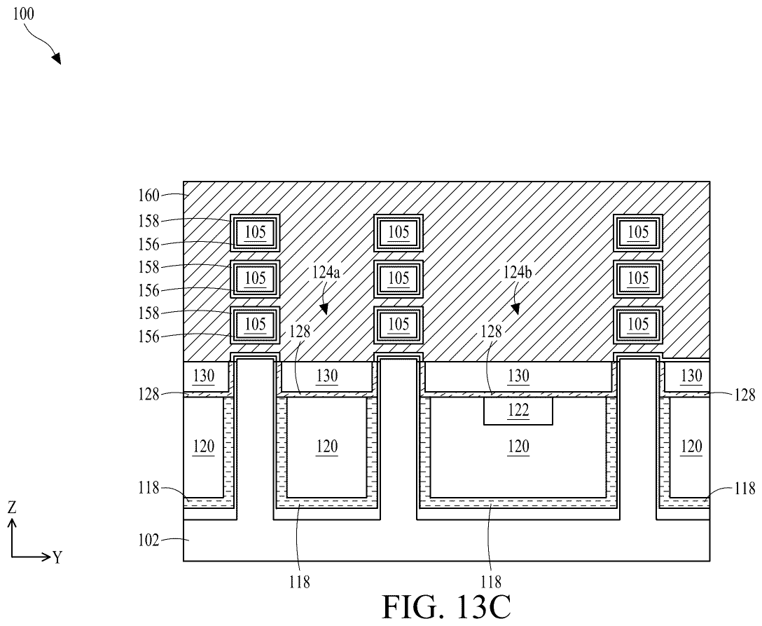

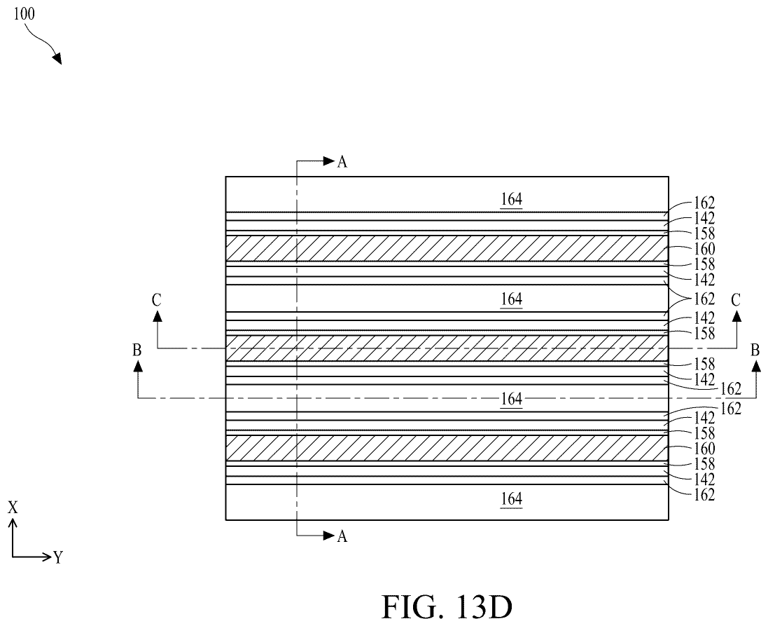

FIG. 13A is a cross-sectional view of the integrated circuit 100, in accordance with some embodiments. FIG. 13B is a cross-sectional view of the integrated circuit 100, in accordance with some embodiments. FIG. 13C is a cross-sectional view of the integrated circuit 100, in accordance with some embodiments. FIG. 13D is a top view of the integrated circuit 100, in accordance with some embodiments. The cross-sectional view of FIG. 13A is taken along cut lines A from FIG. 13D. The cross-sectional view of FIG. 13B is taken along cut lines B from FIG. 13D. The cross-sectional view of FIG. 13C is taken along cut lines C from FIG. 13D.

In FIGS. 13A-13D, a contact etch-stop layer (CESL) 162 and an interlevel dielectric (ILD) layer 164 have been formed, in accordance with some embodiments. The CESL layer 162 can include a thin dielectric layer conformally deposited on exposed surfaces of the source/drain regions 152, the gate spacer layers 142, and on other exposed surfaces. The CESL layer 162 can include SiN, SiC, SiOC, SiOCN, SiON, or other suitable dielectric materials. The CESL 162 can be deposited by CVD, ALD, PVD, or other suitable deposition processes.

The interlevel dielectric layer 164 covers the CESL layer 162. The interlevel dielectric layer 164 fills the remaining spaces between adjacent sacrificial gate structures 134. The interlevel dielectric layer 164 may correspond to a lowest interlevel dielectric layer of the integrated circuit 100. In some embodiments, the interlevel dielectric layer 164 may be termed ILD0. Though not shown herein, additional interlevel dielectric layers may be formed over the interlevel dielectric layer 164. A network of conductive vias and metal lines may be formed in the upper interlevel dielectric layers. The interlevel dielectric layer 164 can include SiO, SiON, SiN, SiC, SiOC, SiOCN, SiON, or other suitable dielectric materials. The interlevel dielectric layer 164 can be deposited by CVD, ALD, PVD, or other suitable deposition processes.

In some embodiments, a CMP process is performed after deposition of the interlevel dielectric layer 164. The result of the CMP process is that the top surfaces of the interlevel dielectric layer 164, the CESL 162, the gate spacer layer 142, and the sacrificial gate layer 136 are coplanar. The CMP process may also reduce the height of the sacrificial gate structures 134.

In FIGS. 13A-13D, the sacrificial gate layer 136 has been removed, in accordance with some embodiments. The sacrificial gate layer 136 can be removed by an etching process that selectively etches the material of the sacrificial gate layer 136 with respect to adjacent materials, such as the gate spacer layers 142. Removal of the sacrificial gate layer 136 results in gate trenches between the gate spacer layers 142.

With reference to FIG. 13A, an etching process has been performed to remove the sacrificial semiconductor nanostructures 107, in accordance with some embodiments. The sacrificial semiconductor nanostructures 107 can be removed by a selective etching process using an etchant that is selective to the material of the channels 105, such that the sacrificial semiconductor nanostructures 107 are removed without substantially etching the channels 105. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 105. The etching process also results in gaps between the channels 105.

In FIGS. 13A-13D, a gate dielectric has been formed, in accordance with some embodiments. The gate dielectric includes an interfacial gate dielectric layer 156 and a high-K gate dielectric layer 158. The interfacial gate dielectric layer 156 has been deposited on exposed portions of the channels 105, in accordance with some embodiments. The interfacial gate dielectric layer 156 forms directly on the exposed portions of the channels 105. The high-K gate dielectric layer 158 forms on the interfacial gate dielectric layer 156 and on other exposed surfaces, such as the exposed sidewalls of the gate spacer layer 142, and the inner spacers 148.

The interfacial gate dielectric layer 156 is wrapped around the channels 105. The interfacial gate dielectric layer 156 can include a dielectric material such as silicon oxide, silicon nitride, or other suitable dielectric materials. The interfacial gate dielectric layer 156 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 156 can be formed by a thermal oxidation process, a chemical vapor deposition (CVD) process, or an atomic layer deposition (ALD) process. The interfacial gate dielectric layer 156 can have a thickness between 0.5 nm and 2 nm. Other materials, deposition processes, and thicknesses can be utilized for the interfacial gate dielectric layer 156 without departing from the scope of the present disclosure.

The high-K gate dielectric layer 158 is deposited in a conformal deposition process. The conformal deposition process deposits the high-K gate dielectric layer 158 on the interfacial gate dielectric layer 156, on the substrate 102, and on the gate spacer layer 142. The high-K gate dielectric layer 158 is wrapped around the channels 105. The high-K gate dielectric layer 158 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 158 may be formed by CVD, ALD, or any suitable method. Other thicknesses, deposition processes, and materials can be utilized for the high-K gate dielectric layer 158 without departing from the scope of the present disclosure.

In FIGS. 13A-13D, a gate metal 160 has been deposited, in accordance with some embodiments. The gate metal 160 is deposited in place of the sacrificial gate layer 136 and the sacrificial semiconductor nanostructures 107. Accordingly, the gate metal 160 is positioned in the gate trench above each stack of channels 105. The gate metal 160 is also wrapped around the channels 105 of each stack.

In FIG. 13B, the dielectric layer 122 of the isolation structure 124b between the source/drain region 152c and the source/drain region 152d has a width in the Y direction between 20 nm and 300 nm and a height in the Z direction between 1 nm and 50 nm. Other dimensions can be utilized without departing from the scope of the present disclosure. In some embodiments, a vertical distance between a top surface of the dielectric layer 120 and the tops of the fins 114 is between 3 nm and 20 nm, though other dimensions can be utilized without departing from the scope of the present disclosure.

In FIG. 13C, the dielectric layer 122 of the isolation structure 124b between adjacent stacks of channels 105 has a width in the Y direction between 20 nm and 300 nm and a height in the Z direction between 1 nm and 50 nm. In some embodiments, the dielectric layer 122 of the isolation structure 124b has a greater height or thickness between adjacent stacks of channels 105 (e.g., in FIG. 13C) than between adjacent source/drain regions 152 (e.g., in FIG. 13B). Other dimensions can be utilized without departing from the scope of the present disclosure.

In FIGS. 13A-13D, a single gate metal 160 is illustrated as a gate electrode of the transistors 101. However, in practice, the gate metal 160 can include multiple gate metals. For example, the gate metal 160 can include one or more liner layers, one or more work function layers, and a gate fill material that fills the remaining spaces between the gate spacer layers 142. The gate metal 160 can include one or more of Ti, TiN, Ta, TaN, Al, Cu, Co, Ru, W, Au, or other suitable conductive materials. The gate metal 160 can be deposited by PVD, ALD, or CVD.

In FIGS. 13A-13D, processing of the transistors 101 is substantially complete. Though not shown in FIGS. 13A-13D, a gate process is performed to remove portions of the gate metal 160 between individual transistors to isolate the gate electrodes of individual transistors. This includes patterning the gate metal 160 and depositing one or more dielectric materials in positions where the gate metal 160 has been removed.

Though not shown in FIGS. 13A-13D, source/drain contacts are formed to electrically connect to the source/drain regions 152. Trenches are formed in the interlevel dielectric layer 164 and the CESL 162 to expose the source/drain regions 152 at selected locations. A silicide is then formed at the surface of the exposed locations of the source/drain regions 152. Source/drain contacts are then formed by filling the trenches with one or more conductive materials in contact with the silicide. The source/drain contacts correspond to conductive plugs or conductive vias that land on the source/drain regions 152 or on the silicide.

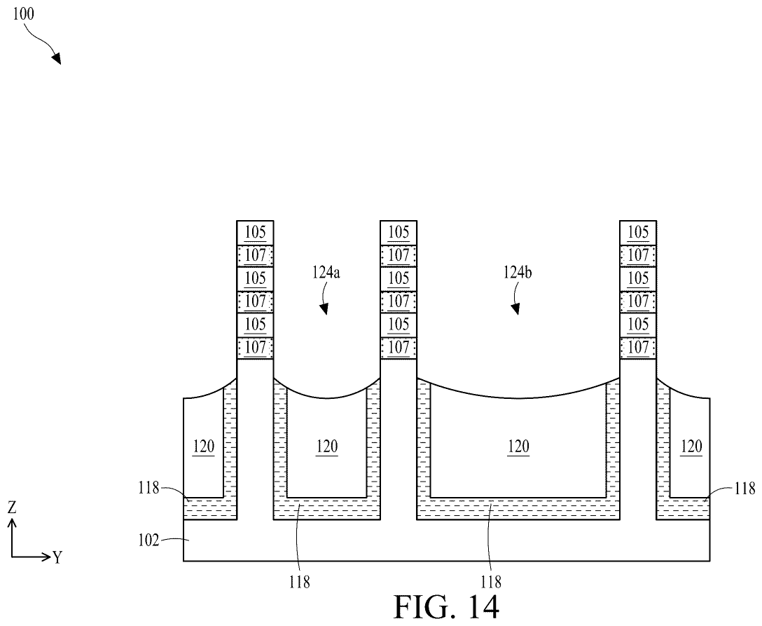

FIG. 14 is a cross-sectional view of the integrated circuit 100, in accordance with some embodiments. The integrated circuit 100 of FIG. 14 is at a similar stage of processing as shown in FIG. 8A. However, in FIG. 14, the isolation structures 124a and 124b have been further recessed. In some embodiments, the recessing process has been entirely removed dielectric layer 122 at the isolation structure 124b. In some embodiments, the hard mask structure 125 of the isolation structure 124 is also recessed in a similar manner. In some embodiments, the top surface of the isolation structures 124b, but the top surface of the isolation structures 124a are not recessed.

In some embodiments, the dielectric layer 118 is not formed. In these cases, the dielectric layer 120 is deposited directly on the substrate 102 in the trenches 116. The dielectric layer 122 is then deposited as described previously.

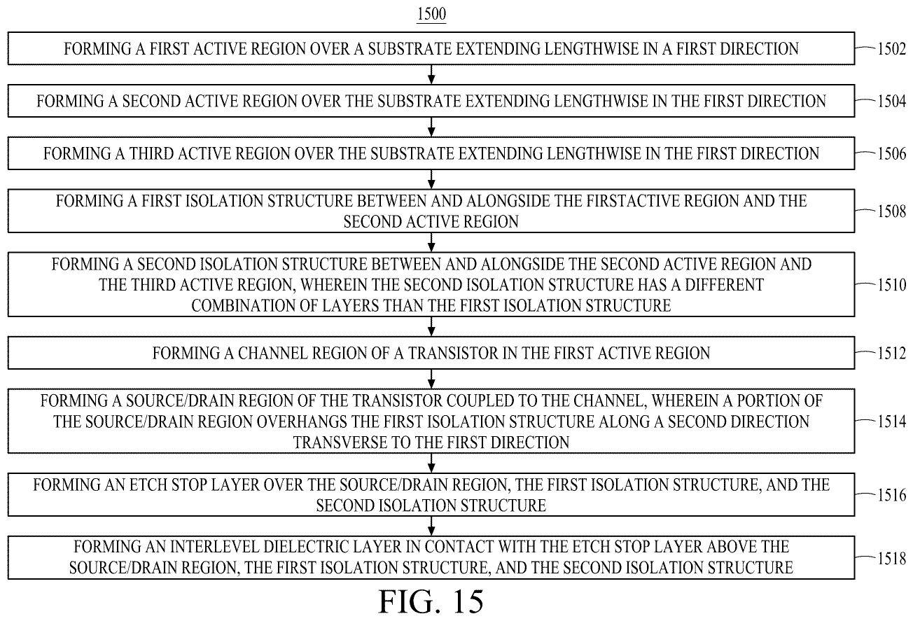

FIG. 15 is a flow diagram of a method 1500 for forming an integrated circuit, in accordance with some embodiments. The method 1500 can utilize the structures, processes, and systems described in relation to FIGS. 1-14. At 1502, the method 1500 includes forming a first active region over a substrate extending lengthwise in a first direction. One example of a substrate is the substrate 102 of FIG. 4A. One example of a first active region is the semiconductor fin/active region 114a of FIG. 4B. At 1504, the method 1500 includes forming a second active region over the substrate extending lengthwise in the first direction. One example of a second active region is the semiconductor fin/active region 114b of FIG. 4B. At 1506, the method 1500 includes forming a third active region over the substrate extending lengthwise in the first direction. One example of a third active region is the semiconductor fin/active region 114c of FIG. 4B. At 1508, the method 1500 includes forming a first isolation structure between and alongside the first active region and the second active region. One example of a first isolation structure is the isolation structure 124a of FIG. 8A. At 1510, the method 1500 includes forming a second isolation structure between and alongside the second active region and the third active region, wherein the second isolation structure has a different combination of layers than the first isolation structure. One example of a second isolation structure is the isolation structure 124b of FIG. 8A. At 1512, the method 1500 includes forming a channel region of a transistor in the first active region. One example of a channel region is the channel 105 of FIG. 13A. At 1514, the method 1500 includes forming a source/drain region of the transistor coupled to the channel, wherein a portion of the source/drain region overhangs the first isolation structure along a second direction transverse to the first direction. One example of a source/drain region is the source/drain region 105a of FIG. 13B. At 1516, the method 1500 includes forming an etch stop layer over the source/drain region, the first isolation structure, and the second isolation structure. One example of an etch stop layer is the CESL 162 of FIG. 13B. At 1518, the method 1500 includes forming an interlevel dielectric layer in contact with the etch stop layer above the source/drain region, the first isolation structure, and the second isolation structure. One example of an interlevel dielectric layer is the interlevel dielectric layer 164 of FIG. 13B.

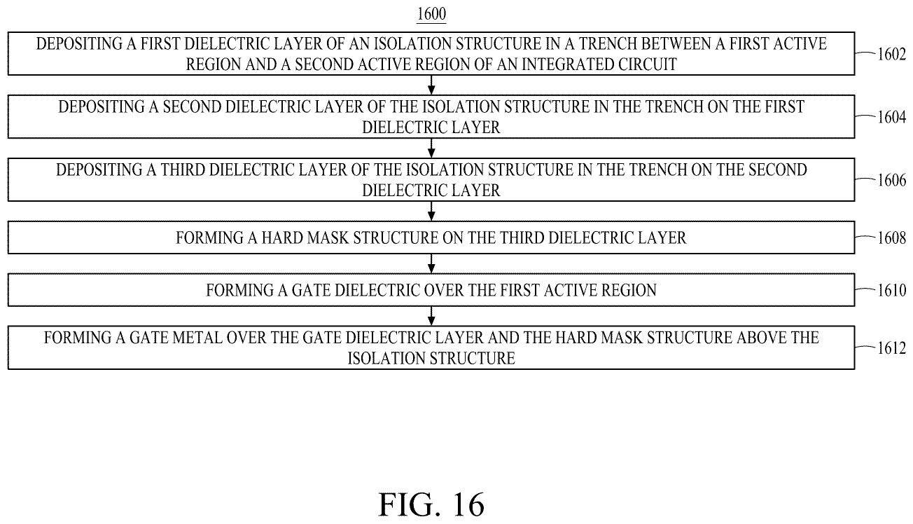

FIG. 16 is a flow diagram of a method 1600 for forming an integrated circuit, in accordance with some embodiments. The method 1600 can utilize the structures, processes, and systems described in relation to FIGS. 1-14. At 1602, the method 1600 includes depositing a first dielectric layer of an isolation structure in a trench between a first active region and a second active region of an integrated circuit. One example of a first active region is the semiconductor fin/active region 114b of FIG. 8A. One example of a second active region is the semiconductor fin/active region 114c of FIG. 8A. One example of a trench is the trench 116 of FIG. 8A. One example of an isolation structure is the isolation structure 124b of FIG. 8A. One example of a first dielectric layer is the dielectric layer 118 of FIG. 8A. At 1604, the method 1600 includes depositing a second dielectric layer of the isolation structure in the trench on the first dielectric layer. One example of a second dielectric layer is the dielectric layer 120 of FIG. 8A. At 1606, the method 1600 includes depositing a third dielectric layer of the isolation structure in the trench on the second dielectric layer. One example of a third dielectric layer is the dielectric layer 122 of FIG. 8A. At 1608, the method 1600 includes forming a hard mask structure on the third dielectric layer. One example of a hard mask structure is the hard mask structure 125b of FIG. 9. At 1610, the method 1600 includes forming a gate dielectric over the first active region. One example of a gate dielectric is the gate dielectric 158 of FIG. 13A. At 1612, the method 1600 includes forming a gate metal over the gate dielectric layer and the hard mask structure above the isolation structure. One example of a gate metal is the gate metal 160 of FIG. 13C.

Embodiments of the disclosure provide isolation structures, such as shallow trench isolation regions, that assist in preventing defects during formation of transistors. Semiconductor fins are formed in the in an integrated circuit. Some adjacent fins are separated by relatively small distances, while other adjacent fins are separated by relatively large distances. Isolation structures are formed between adjacent fins. Formation of the isolation structures includes deposition of three dielectric layers. The first layer is a thin, low-k dielectric layer lining the fins and the trenches between the fins. The second layer is formed on the first layer and is of a different material than the first layer. The third layer is the same material as the first layer. After recessing of the isolation structures, the second layer entirely fills the trenches between fins that are separated by small distances, due to merging. The third layer is present on the second layer in trenches between fins separated by larger distances.

The isolation structures as described above provide various benefits. In particular, the isolation structures help to prevent unwanted bridging between adjacent fins during source/drain epitaxial growth processes. Additionally, the isolation structures can be formed in conjunction with a low temperature annealing process that reduces the oxidation of semiconductor materials of the fins (e.g., oxidation of SiGe layers). This results in transistors having superior electrical characteristics and better overall performance. Furthermore, this can improve wafer yields and overall function of integrated circuits and electronic devices in which the integrated circuits are embedded.

In some embodiments, a method includes forming a first active region over a substrate extending lengthwise in a first direction, forming a second active region over the substrate extending lengthwise in the first direction, and forming a third active region over the substrate extending lengthwise in the first direction. The method includes forming a first isolation structure between and alongside the first active region and the second active region and forming a second isolation structure between and alongside the second active region and the third active region, wherein the second isolation structure has a different combination of layers than the first isolation structure. The method includes forming a channel region of a transistor in the first active region and forming a source/drain region of the transistor coupled to the channel. A portion of the source/drain region overhangs the first isolation structure along a second direction transverse to the first direction. The method includes forming an etch stop layer over the source/drain region, the first isolation structure, and the second isolation structure and forming an interlevel dielectric layer in contact with the etch stop layer above the source/drain region, the first isolation structure, and the second isolation structure.

In some embodiments, a method includes depositing a first dielectric layer of an isolation structure in a trench between a first active region and a second active region of an integrated circuit, depositing a second dielectric layer of the isolation structure in the trench on the first dielectric layer, and depositing a third dielectric layer of the isolation structure in the trench on the second dielectric layer. The method includes forming a hard mask structure on the third dielectric layer, forming a gate dielectric over the first active region, and forming a gate metal over the gate dielectric layer and the hard mask structure above the isolation structure.

In some embodiments, an integrated circuit includes a substrate including a first active region extending in a first direction, a second active region extending in the first direction, and a third active region extending in the third active region. The integrated circuit includes a first isolation structure between and alongside the first active region and the second active region and a second isolation structure between and alongside the second active region and the third active region. The second isolation structure includes more layers of dielectric material than does the first isolation structure. The integrated circuit includes a plurality of stacked channels in the first active region and a source/drain region coupled to the stacked channels. A portion of the source/drain region overhangs the first isolation structure along a second direction transverse to the first direction. The integrated circuit includes a gate dielectric on the stacked channels and a gate metal over the gate dielectric layer, the first isolation structure, and the second isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first active region over a substrate extending lengthwise in a first direction;
forming a second active region over the substrate extending lengthwise in the first direction;
forming a third active region over the substrate extending lengthwise in the first direction;
forming a first isolation structure between and alongside the first active region and the second active region;
forming a second isolation structure between and alongside the second active region and the third active region, wherein the second isolation structure has a different combination of layers than the first isolation structure;
forming a channel region of a transistor in the first active region;
forming a source/drain region of the transistor coupled to the channel, wherein a portion of the source/drain region overhangs the first isolation structure along a second direction transverse to the first direction;
forming an etch stop layer over the source/drain region, the first isolation structure, and the second isolation structure; and
forming an interlevel dielectric layer on the etch stop layer above the source/drain region, the first isolation structure, and the second isolation structure.

2. The method of claim 1, wherein the first and second isolation structures include a first dielectric layer and a second dielectric layer on the first dielectric layer, wherein a top surface of the second dielectric layer has a different shape in the first isolation structure than in the second isolation structure.

3. The method of claim 2, wherein the second isolation structure includes a third dielectric layer on the second dielectric layer.

4. The method of claim 3, wherein the first and third dielectric layers include silicon oxide.

5. The method of claim 4, wherein the second dielectric layer includes silicon nitride.

6. The method of claim 2, further comprising forming a metal layer over the first, second, and third active regions and over the first and second isolation structures.

7. The method of claim 6, wherein the second dielectric layer has a U-shape in the second isolation structure below the gate metal, wherein the second dielectric layer has a has a level and continuous top surface below the gate metal.

8. The method of claim 6, wherein the third dielectric layer has a greater thickness below the gate metal than outside the gate metal.

9. The method of claim 6, further comprising:
forming a first hard mask structure above the first isolation region; and
forming a second hard mask structure above the second isolation region, wherein the gate metal is above the first hard mask structure and the second hard mask structure.

10. The method of claim 9, comprising recessing the first and second hard mask structures laterally outside the gate metal.

11. The method of claim 1, wherein the second and third active regions are spaced farther apart from each other than are the first and second active regions.

12. A method, comprising:
depositing a first dielectric layer of an isolation structure in a trench between a first active region and a second active region of an integrated circuit;
depositing a second dielectric layer of the isolation structure in the trench on the first dielectric layer;
depositing a third dielectric layer of the isolation structure in the trench on the second dielectric layer;
forming a hard mask structure on the third dielectric layer;
forming a gate dielectric over the first active region; and
forming a gate metal over the gate dielectric layer and the hard mask structure above the isolation structure.

13. The method of claim 12, comprising forming the third dielectric layer with a flowable chemical vapor deposition process.

14. The method of claim 13, comprising curing the third dielectric layer by performing a thermal annealing process with a temperature between 300° C and 700° C.

15. The method of claim 12, wherein the first dielectric layer and the third dielectric layer include silicon oxide, wherein the third dielectric layer includes SiN, SiCN, SiOCN, SiOC, or SiC.

16. The method of claim 12, wherein the hard mask layer includes a fourth dielectric layer of silicon oxide and a fifth dielectric layer of silicon nitride.

17. The method of claim 16, further comprising:
forming an etch stop layer on the second dielectric layer and the third dielectric layer at a location laterally outside of the gate metal; and
forming an interlevel dielectric layer on the etch stop layer.

18. An integrated circuit, comprising:
a first active region extending in a first direction, a second active region extending in the first direction, and a third active region extending in the third active region;
a first isolation structure between and alongside the first active region and the second active region;
a second isolation structure between and alongside the second active region and the third active region, wherein the second isolation structure includes more layers of dielectric material than does the first isolation structure;
a plurality of stacked channels in the first active region;
a source/drain region coupled to the stacked channels, wherein a portion of the source/drain region overhangs the first isolation structure along a second direction transverse to the first direction;
a gate dielectric on the stacked channels; and
a gate metal over the gate dielectric layer, the first isolation structure, and the second isolation structure.

19. The integrated circuit of claim 18, further comprising:
a first hard mask structure between the first isolation structure and the metal layer; and
a second hard mask structure between the second isolation structure and the gate metal.

20. The integrated circuit of claim 18, wherein the second isolation structure includes:
a first dielectric layer having a U-shaped profile along the second direction below the gate metal;
a second dielectric layer on the first dielectric layer having a U-shaped profile along the second direction below the gate metal; and
a third dielectric layer on the second dielectric layer below the gate metal.
